(19) United States
(12) Patent Application Publication
(10) Pub. No.: US 2018/0304603 A1
(43) Pub. Date: Oct. 25, 2018

(54) BUMP BASE REINFORCEMENT SHEET

(71) Applicant: Nitto Denko Corporation, Ibaraki-shi, Osaka (JP)

(72) Inventors: Chie Iino, Ibaraki-shi, Osaka (JP); Goji Shiga, Ibaraki-shi, Osaka (JP)

(21) Appl. No.: 15/770,567

(22) PCT Filed: Oct. 13, 2016
(86) PCT No.: PCT/JP2016/080390

§ 371 Date: Apr. 24, 2018

(30) Foreign Application Priority Data
Oct. 28, 2015 (JP) 2015-211968

(51) Int. Cl. B32B 27/30; B32B 27/08; B32B 27/36; H01L 23/31; H01L 23/00

(52) U.S. Cl. CPC B32B 27/308; B32B 27/306; B32B 27/08; B32B 27/365; B32B 2255/10; H01L 24/91; H01L 2924/3512; H01L 2224/92125; H01L 23/3157

(57) ABSTRACT

Provided is a bump base reinforcement sheet which can reinforce a base portion of even a solder bump having a large diameter on a primary mounted substrate side and achieve good electrical connection with a secondary mounted substrate. A bump base reinforcement sheet includes: a base material sheet; and a thermosetting resin sheet laminated on the base material sheet, in which a thickness t [μm] of the base material sheet and a minimum melt viscosity η [Pa·s] of the thermosetting resin sheet at 50 to 180° C. satisfy the following relational expression:

150≤t·η≤100000.

### TECHNICAL FIELD

The present invention relates to a bump base reinforcement sheet.

### BACKGROUND ART

The demand for high density mounting associated with downsizing and thinning of electronic instruments has been rapidly increased particularly in applications of portable electronic instruments such as mobile phones. Accordingly, for semiconductor packages, the surface mounting type suitable for high density mounting has become mainstream in place of the conventional pin insertion type. In the surface mounting type, a semiconductor device with a semiconductor element resin-sealed thereto is directly soldered to a printed board etc. for secondary mounting with a connecting terminal such as a solder bump interposed therebetween.

Here, in applications of portable electronic instruments, impact resistance is required because falling impact is often applied. On the other hand, in secondary mounting as described above, a space between a primary mounted semiconductor device and a wiring substrate is filled with a sealing resin in order to secure connection reliability between the primary mounted semiconductor device and the substrate. As the sealing resin, liquid sealing resins are widely used, but it is difficult to adjust the injection position and the injection amount of the sealing resin because the sealing resin is liquid, or in the case of a relatively large solder bump for secondary mounting, the gap between the solder bump and the substrate becomes wide to increase the injection amount. Accordingly, a technique has been proposed in which using a thermosetting resin sheet, a region in the vicinity of the connection part between a solder bump and a secondary mounted substrate, rather than the whole space between a semiconductor device and a substrate, is intensively reinforced (Patent Document 1)

### PRIOR ART DOCUMENT

### Patent Document

Patent Document 1: Japanese Patent No. 4699189

### SUMMARY OF THE INVENTION

### Problems to be Solved by the Invention

However, in particular, in a solder bump having a diameter (height) increased to about 200 μm, falling impact applied to a portable electronic instrument, and a difference in linear expansion coefficient between a solder bump and a primary mounted substrate, etc. may cause cracks not at a solder connection portion on the primary mounted substrate but at a base portion of a solder bump on the secondary mounted substrate side, leading to occurrence of a functional disorder such as a connection failure. The large-diameter solder bump is insufficiently embedded into the thermosetting resin sheet, so that the solder bump is not exposed, or the solder bump is crushed, which may make it impossible to achieve electrical connection with a secondary mounted substrate.

An object of the present invention is to provide a bump base reinforcement sheet which can reinforce a base portion of even a solder bump having a large diameter on a primary mounted substrate side and achieve good electrical connection with a secondary mounted substrate.

### Means for Solving the Problems

The present inventors have extensively conducted studies, and resultantly found that by employing the configuration described below, the above-mentioned object can be achieved, leading to completion of the present invention.

That is, a bump base reinforcement sheet of the present invention includes: a base material sheet; and a thermosetting resin sheet laminated on the base material sheet, in which a thickness t [μm] of the base material sheet and a minimum melt viscosity η [Pa·s] of the thermosetting resin sheet at 50 to 180° C. satisfy a relational expression below:

150≤t·η≤100000.

In the bump base reinforcement sheet, the thickness t [μm] of the sheet and the minimum melt viscosity η [Pa·s] of the thermosetting resin sheet at 50 to 180° C. satisfy a predetermined relational expression (hereinafter also referred to as “t·η relational expression”). This makes it possible to embed the thermosetting resin sheet up to a base portion of a solder bump on a primary mounted substrate side when the bump base reinforcement sheet is bonded to the solder bump side of a primary mounted semiconductor, which allows the base portion of the solder bump to be reinforced. As a result, an effect of the difference in linear expansion coefficient between the primary mounted semiconductor device and the solder bump is alleviated to prevent cracks in the base portion of the solder bump, so that the reliability of a secondary mounted semiconductor device can be improved. By satisfying the above relationship, the solder bump can be exposed from the thermosetting resin sheet without crushing the solder bump. As a result, good electrical connection between the solder bump and a secondary mounted substrate can be achieved. In a range less than the lower limit of the t·η relational expression, the thickness of the base material sheet or the minimum melt viscosity of the thermosetting resin sheet is small, so that the strength or rigidity of the bump base reinforcement sheet decreases. This makes it impossible to embed the thermosetting resin sheet up to the vicinity of the base of the solder bump, or to expose the solder bump from the thermosetting resin sheet. On the other hand, in a range exceeding the upper limit of the t·η relational expression, the thickness of the base material sheet or the minimum melt viscosity of the thermosetting resin sheet is too large, so that the strength (rigidity) of the bump base reinforcement sheet is too high. This causes the solder bump to be crushed, or makes it difficult to expose the solder bump from the thermosetting resin sheet.

It is preferable that the base material sheet has a thickness of 50 to 100 μm. When the thickness of the base material sheet is within the above range, the t·η relational expression can be suitably satisfied, which can efficiently achieve reinforcement of the base of the solder bump and electrical connection with the secondary mounted substrate.

It is preferable that the base material sheet has a storage modulus E′ at 175° C. of 5×10⁶ Pa or more and 5×10⁷ Pa or less. When the storage modulus E′ is equal to or lower than the upper limit, it is possible to impart flexibility that allows the base material sheet to follow the shape of the solder bump, so that the top portion of the solder bump can be exposed from the thermosetting resin sheet without crushing the solder bump. When the storage modulus E′ is equal to or more than the lower limit, it is possible to impart appropriate rigidity to the base material sheet, to sweep away resin present near the top portion of the solder bump, and to expose the top portion of the solder bump from the thermosetting resin sheet.

It is preferable that the base material sheet is a fluorine-based sheet. The fluorine-based sheet has a good balance between flexibility and rigidity. Since the fluorine-based sheet has releasability, a releasing agent provided on a conventional PET sheet or the like is not required, whereby the transfer of the releasing agent to the thermosetting resin sheet can also be prevented.

It is preferable that the fluorine-based sheet contains a copolymer of a fluorine-containing monomer and an ethylene monomer. The fluorine-based sheet containing such a copolymer makes it possible to achieve both flexibility and rigidity of the base material sheet at a higher level. Since the properties of the base material sheet can be controlled by changing the blending ratio of both the monomers, the degree of freedom in designing the bump base reinforcement sheet can be improved.

### BRIEF DESCRIPTION OF THE DRAWINGS

FIG. 1 is a sectional schematic view showing a reinforcement sheet according to one embodiment of the present invention.

FIG. 2A is a sectional schematic view showing one step of a process for production of a semiconductor device according to one embodiment of the present invention.

FIG. 2B is a sectional schematic view showing one step of the process for production of a semiconductor device according to one embodiment of the present invention.

FIG. 2C is a sectional schematic view showing one step of the process for production of a semiconductor device according to one embodiment of the present invention.

FIG. 2D is a sectional schematic view showing one step of the process for production of a semiconductor device according to one embodiment of the present invention.

FIG. 2E is a sectional schematic view showing one step of the process for production of a semiconductor device according to one embodiment of the present invention.

FIG. 3 is a sectional schematic view showing one step of a process for production of a semiconductor device according to another embodiment of the present invention.

### MODE FOR CARRYING OUT THE INVENTION

Embodiments of the present invention will be described below with reference to the drawings. However, in part or all of the drawings, parts unnecessary for explanation are omitted, and there are parts shown by magnification or reduction in order to facilitate explanation. Terms indicating a positional relationship such as upper and lower are used in order to merely facilitate explanation, and there is no intention to limit the configuration of the present invention at all.

### First Embodiment

First, a bump base reinforcement sheet will be described, and a method of producing a secondary mounted semiconductor device including the bump base reinforcement sheet will be then described. In the first embodiment, a package with a semiconductor chip flip-chip-mounted on an interposer as a primary mounted semiconductor device is used.

(Bump Base Reinforcement Sheet)

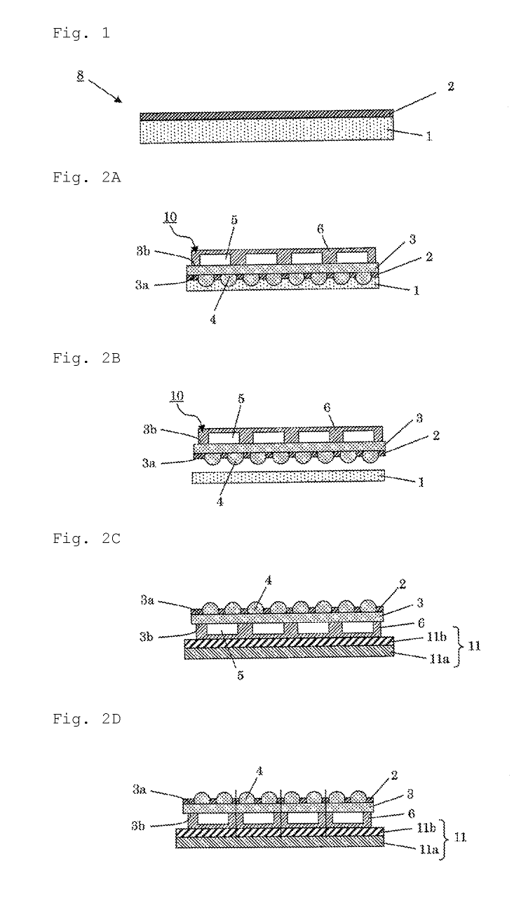

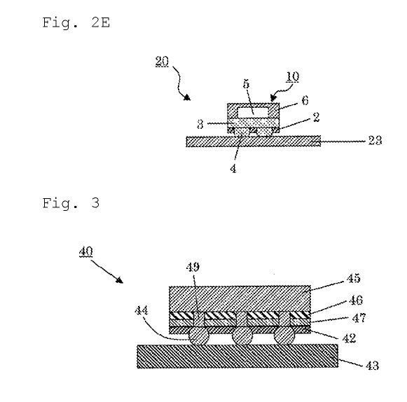

As shown in FIG. 1, a bump base reinforcement sheet (hereinafter also simply referred to as a “reinforcement sheet”) 8 includes a base material sheet 1 and a thermosetting resin sheet 2 laminated on the base material sheet 1. As long as the thermosetting resin sheet 2 is provided so as to have a size sufficient for bonding the thermosetting resin sheet 2 to a resin sealing assembly of a primary mounted semiconductor device 10 (see FIG. 2A), the thermosetting resin sheet 2 may be laminated on the entire surface of the base material sheet 1, or may be laminated on a part of the base material sheet 1.

In the reinforcement sheet 8, the thickness t [μm] of the base material sheet 1 and the minimum melt viscosity η [Pa·s] of the thermosetting resin sheet 2 at 50 to 180° C. satisfy the following relational expression:

150≤t·η≤100000.

Furthermore, in the reinforcement sheet 8, it is preferable that the thickness t [μm] of the base material sheet 1 and the minimum melt viscosity η [Pa·s] of the thermosetting resin sheet 2 at 50 to 180° C. satisfy the following relational expression:

200≤t·η≤80000.

When the above-mentioned t·η relational expression is satisfied, the thermosetting resin sheet can be embedded up to a base portion of a solder bump on a primary mounted substrate side when the bump base reinforcement sheet is bonded to a solder bump forming surface of the primary mounted semiconductor, so that the base portion of the solder bump can be reinforced. As a result, an effect of the difference in linear expansion coefficient between the primary mounted semiconductor device and the solder bump is alleviated to prevent cracks in the base portion of the solder bump, so that the reliability of a secondary mounted semiconductor device can be improved. The solder bump can be exposed from the thermosetting resin sheet without being crushed, and as a result, good electrical connection between the solder bump and a secondary mounted substrate can be achieved.

(Base Material Sheet)

The base material sheet 1 serves a member serving as a strength matrix of the reinforcement sheet 8. A material for forming the base material sheet 1 is not particularly limited as long as the material can impart flexibility and rigidity. The base material sheet 1 is preferably a fluorine-based sheet. Examples of the fluorine-based sheet include sheets formed of polytetrafluoroethylene (PTFE), a copolymer of tetrafluoroethylene and perfluoroalkyl vinyl ether (PFA), a copolymer of tetrafluoroethylene and hexafluoropropylene (FEP), polychlorotrifluoroethylene (PCTFE), a copolymer of tetrafluoroethylene and ethylene (ETFE), polyvinylidene fluoride (PVdF), polyvinyl fluoride (PVF) and the like. Among them, from the viewpoint of a balance between flexibility and rigidity, a copolymer of a fluorine-containing monomer and an ethylene monomer is preferable, and a copolymer of tetrafluoroethylene and ethylene (ETFE) is more preferable. The fluorine-based sheet itself has releasability, so that it is particularly unnecessary to use a release agent. This makes it possible to simplify the production process of the reinforcement sheet and to reduce the cost.

The blending proportion of the ethylene monomer is preferably 60 to 110 with respect to 100 of the fluorine-containing monomer in molar ratio. Such a blending ratio makes it possible to improve the balance between flexibility and rigidity of the base material sheet, and to control flexibility and rigidity of the base material sheet according to an intended object to be reinforced.

The thickness of the base material sheet is preferably 40 to 100 μm, and more preferably 50 to 75 μm. When the thickness of the base material sheet is within the above range, the t·η relational expression can be suitably satisfied, which can efficiently achieve reinforcement of the base of the solder bump and electrical connection with the secondary mounted substrate.

The storage elastic modulus E′ of the base material sheet 1 at 175° C. is preferably 5×10⁶ Pa or more and 5×10⁷ Pa or less, and more preferably 9×10⁶ Pa or more and 4×10⁷ Pa or less. When the storage modulus E′ is equal to or lower than the upper limit, it is possible to impart flexibility that allows the base material sheet to follow the shape of the solder bump, so that the top portion of the solder bump can be exposed from the thermosetting resin sheet without crushing the solder bump. When the storage modulus E′ is equal to or more than the lower limit, it is possible to impart appropriate rigidity to the base material sheet, to sweep away resin present near the top portion of the solder bump, and to expose the top portion of the solder bump from the thermosetting resin sheet.

The storage elastic modulus of the base material sheet is measured as follows. From the base material sheet, a measurement sample is obtained, which has a length of 20 mm, a width of 2 mm, and a thickness of 200 μm. The storage elastic modulus of the measurement sample is measured with RSA 3 manufactured by TA Instruments. Specifically, a storage elastic modulus in a temperature range of −50 to 300° C. is measured under conditions of a frequency of 1 Hz, a strain of 0.05%, and a temperature rise rate of 10° C./minute, and a storage elastic modulus at 175° C. (E′) can be read and obtained.

The surface of the base material sheet 1 can be subjected to a common surface treatment, for example, a chemical or physical treatment such as a plasma treatment, a chromic acid treatment, ozone exposure, flame exposure, high pressure electric shock exposure, or an ionized radiation treatment for improving adhesion with the thermosetting resin sheet 2 adjacent to the base material sheet 1 and retention property or the like.

(Thermosetting Resin Sheet)

The thermosetting resin sheet 2 in the present embodiment can be suitably used as a reinforcing film for reinforcing, on the primary mounted substrate side, the base portion of the solder bump of the primary mounted semiconductor device that is secondarily mounted on the surface.

Suitable aspects of a resin composition for forming the thermosetting resin sheet will be described below. From the viewpoint of improving the heat resistance and stability of the cured thermosetting resin sheet, preferably, the resin composition further contains a thermosetting resin in addition to the elastomer. Specific examples of the preferred resin composition include epoxy resin compositions containing components A to E shown below.

Component A: epoxy resin

Component B: phenol resin

Component C: elastomer

Component D: organic filler

Component E: curing accelerator

### (Component A)

An epoxy resin (component A) as the thermosetting resin is not particularly limited. Various kinds of epoxy resins can be used such as, for example, a triphenylmethane-type epoxy resin, a cresol novolac-type epoxy resin, a biphenyl-type epoxy resin, a modified bisphenol A-type epoxy resin, a bisphenol A-type epoxy resin, a bisphenol F-type epoxy resin, a modified bisphenol F-type epoxy resin, dicyclopentadiene-type epoxy resin, a phenol novolac-type epoxy resin and a phenoxy resin. These epoxy resins may be used alone or in combination of two or more thereof.

An epoxy resin which has an epoxy equivalent of 150 to 250 and a softening point or melting point of 50 to 130° C. and is solid at ordinary temperature is preferred from the viewpoint of securing toughness after curing of the epoxy resin and reactivity of the epoxy resin, and particularly a triphenylmethane-type epoxy resin, a cresol novolac-type epoxy resin and a biphenyl-type epoxy resin are preferred from the viewpoint of reliability.

A modified bisphenol A-type epoxy resin having a flexible backbone of an acetal group, a polyoxyalkylene group or the like is preferred from the viewpoint of low stress, and a modified bisphenol A-type epoxy resin having an acetal group can be especially suitably used because it is liquid and has good handling characteristics.

The content of the epoxy resin (component A) is preferably set in a range of 1 to 10% by weight based on the total amount of the epoxy resin composition.

### (Component B)

The phenol resin (component B) is not particularly limited as long as it can be used as the thermosetting resin and it causes a curing reaction with the epoxy resin (component A). For example, a phenol novolac resin, a phenol aralkyl resin, a biphenyl aralkyl resin, a dicyclopentadiene-type phenol resin, a cresol novolac resin, a resol resin and the like are used. These phenol resins may be used alone or in combination of two or more thereof.

As the phenol resin, a phenol resin having a hydroxyl equivalent of 70 to 250 and a softening point of 50 to 110° C. is preferably used from the viewpoint of reactivity with the epoxy resin (component A), and particularly a phenol novolac resin can be suitably used because of its high curing reactivity. A phenol resin having low hygroscopicity, such as a phenol aralkyl resin and a biphenyl aralkyl resin, can also be suitably used from the viewpoint of reliability.

The epoxy resin (component A) and the phenol resin (component B) are blended in such a ratio that the total amount of hydroxyl groups in the phenol resin (component B) is preferably 0.7 to 1.5 equivalents, more preferably 0.9 to 1.2 equivalents, based on 1 equivalent of epoxy groups in the epoxy resin (component A) from the viewpoint of curing reactivity.

### (Component C)

An elastomer (component C) used with the epoxy resin (component A) and the phenol resin (component B) is not particularly limited, and various acrylic copolymers and rubber components or the like can be used, for example. From the viewpoint that the dispersibility of the component C in the epoxy resin (component A), and the heat resistance, flexibility, and strength of the obtained thermosetting resin sheet can be improved, the component C preferably contains a rubber component. The rubber component is preferably at least one selected from the group consisting of a butadiene-based rubber, a styrene-based rubber, an acrylic rubber, and a silicone-based rubber. These may be used alone or in combinations of two or more.

The content of the elastomer (component C) is 1.0 to 3.5% by weight, preferably 1.0 to 3.0% by weight based on the total amount of the epoxy resin composition. If the content of the elastomer (component C) is less than 1.0% by weight, it becomes difficult to secure the plasticity and flexibility of the thermosetting resin sheet 2, and further it becomes difficult to perform resin sealing while suppressing the warp of the thermosetting resin sheet. If conversely the above-described content is more than 3.5% by weight, there is the tendency that the melt viscosity of the thermosetting resin sheet 2 is increased to deteriorate the embedding property of a solder bump, and the strength and heat resistance of a cured body of the thermosetting resin sheet 2 are reduced.

### (Component D)

The inorganic filler (component D) is not particularly limited, various kinds of previously known fillers can be used, and examples thereof include powders of quartz glass, talc, silica (fused silica, crystalline silica, etc.), alumina, aluminum nitride, silicon nitride and boron nitride. They may be used alone or in combination of two or more thereof.

Particularly, silica powders are preferably used because the thermal linear expansion coefficient of a cured body of the epoxy resin composition is reduced to thereby reduce internal stress, and resultantly the warp of the thermosetting resin sheet 2 after reinforcing of the primary mounted semiconductor device can be suppressed, and among silica powders, a fused silica powder is more preferably used. Examples of the fused silica powder include a spherical fused silica powder and a crushed fused silica powder, but a spherical fused silica powder is especially preferably used from the viewpoint of fluidity. Particularly, those having an average particle diameter of 55 jam or less are preferably used, those having an average particle diameter ranging from 0.1 to 30 μm are further preferably used, and those having an average particle diameter ranging from 0.5 to 20 μm are especially preferably used. When the average particle diameter exceeds the upper limit, inorganic particles are easily caught between the thermosetting resin sheet and the primary mounted substrate, so that the reinforcement level may be reduced to deteriorate impact resistance and connection reliability of the secondary mounted semiconductor device. When the average particle diameter of the inorganic filler is less than the lower limit, particles are easily aggregated, so that it may be difficult to form the thermosetting resin sheet, and at the same time, the fillable amount of the inorganic filler may be decreased, so that warpage may occur after thermosetting resin sheet is sealed and cured.

The average particle diameter can be derived by making a measurement with a laser diffraction scattering grain size distribution measuring device using a sample that is randomly extracted from a population.

The content of the inorganic filler (component D) is preferably 70 to 90% by volume (81 to 94% by weight since a silica particle has a specific gravity of 2.2 g/cm³), more preferably 74 to 85% by volume (84 to 91% by weight in the case of a silica particle), and still more preferably 76 to 83% by volume (85 to 90% by weight in the case of a silica particle) based on the total amount of the epoxy resin composition. When the content of the inorganic filler (component D) is less than 70% by volume, the amount of an organic component is large, so that the amount of shrinkage due to thermal curing is increased, which may cause warpage in the primary mounted semiconductor device when the resin is thermally cured after sealing. The storage elastic modulus may be decreased and the stress relaxation reliability of the solder bump on the base region may be greatly impaired. On the other hand, when the content is more than 90% by volume, the flexibility and fluidity of the thermosetting resin sheet 2 are deteriorated, so that the irregularities of the primary mounted substrate and the space of the base of the solder bump are not sufficiently filled with the thermosetting resin sheet 2, which may cause voids and cracks.

### (Component E)

The curing accelerator (component E) is not particularly limited as long as it causes curing of the epoxy resin and the phenol resin to proceed, but organic phosphorus-based compounds such as triphenylphosphine and tetraphenylphosphonium tetraphenylborate, and imidazole-based compounds are suitably used from the viewpoint of curability and keeping quality. These curing accelerators may be used alone or in combination with other curing accelerators.

The content of the curing accelerator (component E) is preferably 0.1 to 5 parts by weight based on 100 parts by weight of the total of the epoxy resin (component A) and the phenol resin (component B).

### (Other Components)

To the epoxy resin composition may be added a flame retardant component in addition to the components A to E. As the flame retardant component, various kinds of metal hydroxides such as, for example, aluminum hydroxide, magnesium hydroxide, iron hydroxide, calcium hydroxide, tin hydroxide and conjugated metal hydroxides can be used. As the flame retardant component, not only the above-mentioned metal hydroxides but also a phosphazene compound can be used. As the phosphazene compound, for example, SPR-100, SA-100 and SP-100 (each manufactured by Otsuka Chemical Co., Ltd.), FP-100 and FP-110 (each manufactured by FUSHIMI Pharmaceutical Co., Ltd.) and the like are available as commercial products. As the cyclic phosphazene oligomer represented by the above formula (3), for example, FP-100 and FP-110 (each manufactured by FUSHIMI Pharmaceutical Co., Ltd.) and the like are available as commercial products. The content of phosphorus elements contained in the phosphazene compound is preferably 12% by weight or more from the viewpoint that it exhibits a flame retardant effect even in a small amount.

Besides the above mentioned components, other additives can be blended with the epoxy resin composition as necessary. Examples of other additives include a pigment such as carbon black, a silane coupling agent and an ion trapping agent. Examples of the silane coupling agent include β-(3,4-epoxycyclohexyl)ethyltrimethoxysilane, γ-glycidoxypropyltrimethoxysilane and γ-glycidoxypropylmethyldiethoxysilane. These compounds can be used alone, or in combination of two or more thereof. Examples of the ion trapping agent include a hydrotalcite and bismuth hydroxide. They can be used alone, or in combination of two or more thereof.

A flux may be added to the thermosetting resin sheet 2 for removing an oxide film on the surface of a solder bump to facilitate mounting of a primary mounted semiconductor device onto a wiring substrate. The flux is not particularly limited, a previously known compound having an a flux action can be used, and examples thereof include diphenolic acid, adipic acid, acetylsalicylic acid, benzoic acid, benzilic acid, azelaic acid, benzylbenzoic acid, malonic acid, 2,2-bis(hydroxymethyl)propionic acid, salicylic acid, o-methoxybenzoic acid, m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide and dihydrazide adipate. The added amount of the flux may be such an amount that the flux action is exhibited, and is normally about 0.1 to 20 parts by weight based on 100 parts by weight of the resin component contained in the thermosetting resin sheet.

In this embodiment, the minimum melt viscosity η of the thermosetting resin sheet 2 at 50 to 180° C. before heat curing is preferably 1000 Pa·s or less, more preferably not less than 60 Pa·s and not more than 500 Pa·s. When the minimum melt viscosity η at 50 to 180° C., which is equivalent to a bonding temperature, is in the above-mentioned range, entry of the solder bump 4 (see FIG. 2A) into the thermosetting resin sheet 2 can be facilitated, and the resin on the solder bump can be easily swept away, which allows the solder bump to be exposed. If the minimum melt viscosity exceeds the upper limit, the resin on the solder bump is less likely to flow during sealing, and the top portion of the solder bump may be covered with the resin as it is, or the resin may be pushed as it is, which may cause crushing of the solder bump.

The thickness of the thermosetting resin sheet 2 (the total thickness in the case of multiple layers) is not particularly limited, and may be appropriately set in consideration of the range of the base portion to be reinforced in the solder bump 4. In view of the strength of the thermosetting resin sheet 2 and reinforcement of the base portion of the solder bump 4, the thickness of the thermosetting resin sheet 2 is preferably less than the height of the solder bump, and may be specifically 30 μm or more and 100 μm or less.

The surface of the thermosetting resin sheet 2 on a side opposite to the base material sheet 1 is preferably protected by a separator (not illustrated). The separator has a function as a protective material that protects the thermosetting resin sheet 2 until the reinforcement sheet is put to practical use. The separator is peeled off at the time of attaching the primary mounted semiconductor device 10 on the thermosetting resin sheet 2 of the reinforcement sheet 8. As the separator, a film of polyethylene terephthalate (PET), polyethylene or polypropylene, a plastic film or paper surface-coated with a release agent such as a fluorine-based release agent or a long chain alkyl acrylate-based release agent, or the like can be used.

(Method for Preparing Thermosetting Resin Sheet)

As a method for preparing the thermosetting resin sheet, a kneading extrusion method and a coating method can be suitably adopted. The methods will be described below.

(Kneading Extrusion Method)

The kneading extruding method includes a kneading step of preparing a kneaded material and a molding step of molding the kneaded material into a sheet shape to obtain a thermosetting resin sheet.

First, an epoxy resin composition is prepared by mixing the components described above. The mixing method is not particularly limited as long as the components are uniformly dispersed and mixed. Thereafter, a kneaded product is prepared by kneading the blend components containing an elastomer directly with a kneader or the like.

Specifically, components including the components A to E and other additives as necessary are mixed using known means such as a mixer, and the mixture is then melt-kneaded to prepare a kneaded product. The method for performing melt-kneading is not particularly limited, and examples thereof include methods of performing melt-kneading by a known kneader such as a mixing roll, a pressure kneader or an extruder. As the above-mentioned kneader, for example, a kneader can be suitably used, which includes a kneading screw having, a portion where in a part of a shaft direction, the protrusion amount of a screw blade from a screw shaft is smaller than the protrusion amount of a screw blade from a screw shaft in other portions, or a kneading screw having, in a part of a shaft direction, no screw blade. In the portion where the protrusion amount of a screw blade is small or the portion having no screw blade, the shearing force and stirring level are lowered, and consequently the compression ratio of a kneaded product is increased, so that entrapped air can be removed, thus making it possible to suppress generation of pores in the kneaded product obtained.

Kneading conditions are not particularly limited as long as the temperature is equal to or higher than the softening points of the components described above, and the temperature is, for example, 30 to 150° C., and preferably 40 to 140° C., further preferably 60 to 120° C. when considering the heat-curability of the epoxy resin, and the time is, for example, 1 to 30 minutes, preferably 5 to 15 minutes. In this way, a kneaded product can be prepared.

### (Molding Step)

Through molding the resulting kneaded product into a sheet-like shape by extrusion molding, the thermosetting resin sheet 2 can be obtained. Specifically, the kneaded product after melt-kneading is extrusion-molded while it is kept at a high temperature without being cooled, whereby the thermosetting resin sheet 2 can be formed. The extrusion method for this purpose is not particularly limited, and examples thereof include a T die extrusion method, a rolling method, a roll kneading method, a co-extrusion method and a calender molding method. The extrusion temperature is not particularly limited as long as it is equal to or higher than the softening points of the components described above, but the extrusion temperature is, for example, 40 to 150° C., preferably 50 to 140° C., further preferably 70 to 120° C. when considering the heat curability and moldability of the epoxy resin. In this way, the thermosetting resin sheet 2 can be formed.

The thermosetting resin sheet thus obtained may be laminated as necessary so as to have a desired thickness, and used. In other words, the thermosetting resin sheet may be used in the form of a monolayer structure, or may be used as a laminate formed by laminating the thermosetting resin sheet into a multilayer structure having two or more layers.

(Coating Method)

In the coating method, a varnish prepared by dissolving or dispersing components in an organic solvent or the like is coated and formed into a sheet.

As a specific preparation procedure using a varnish, the components A to E and other additives as necessary are appropriately mixed in accordance with a usual method, and the mixture is uniformly dissolved or dispersed in an organic solvent to prepare a varnish. Then, the varnish is coated onto a support of polyester or the like, and dried, whereby the thermosetting resin sheet 2 can be obtained. A release sheet such as a polyester film may be laminated as necessary for protecting the surface of the sealing sheet.

The organic solvent is not particularly limited, and various kinds of previously known organic solvents, for example, methyl ethyl ketone, acetone, cyclohexanone, dioxane, diethyl ketone, toluene, ethyl acetate and the like can be used. They may be used alone or in combination of two or more thereof. Normally, it is preferred to use the organic solvent in such a manner that the solid concentration of the varnish ranges from 30 to 95% by weight.

The thickness of the sheet after drying of the organic solvent is not particularly limited, but is normally set to preferably 5 to 100 μm, more preferably 20 to 70 μm, from the viewpoint of uniformity of the thickness and the amount of a residual solvent. A plurality of sheets after drying may be stacked to have a desired thickness. Drying is performed under conditions of 100 to 150° C. and about 1 to 5 minutes after varnish coating.

(Method for Producing Secondary Mounted Semiconductor Device)

One embodiment of the present invention includes a method for producing a secondary mounted semiconductor device in which a primary mounted semiconductor device having a solder bump formed on a first main surface is electrically connected to a wiring substrate via the solder bump, the method including the steps of:

(A) bonding the bump base reinforcement sheet to the first main surface of the primary mounted semiconductor device while the solder bump is exposed from a thermosetting resin sheet;

(B) peeling off the thermosetting resin sheet and a base material sheet in the bump base reinforcement sheet to obtain a primary mounted semiconductor device with the thermosetting resin sheet;

(C) subjecting the thermosetting resin sheet to a heat treatment; and

(D) electrically connecting the primary mounted semiconductor device with the thermosetting resin layer to the wiring substrate via the solder bump.

[Step (A)]

In the step (A), a predetermined reinforcement sheet is bonded to the first main surface (solder bump forming surface) of the primary mounted semiconductor device. At this time, the top portion of the solder bump is exposed from the thermosetting resin sheet.

(Primary Mounted Semiconductor Device)

As shown in FIG. 2A, the primary mounted semiconductor device 10 according to this embodiment may be a semiconductor device with the solder bump 4 formed on a first main surface 3a. For example, the primary mounted semiconductor device 10 refers to a semiconductor device with a semiconductor chip or semiconductor element 5 connected to the solder bump 4 (also referred to as a solder ball, a conductive ball or the like) through so called an interposer or substrate 3, and is usually sealed with a sealing resin 6 to form a package. Therefore, strictly speaking, the primary mounted semiconductor device 10 shown in FIG. 2A is a sealing assembly in which a plurality of primary mounted semiconductor devices are sealed with a resin, but in this specification, the former and the latter may be referred to as a primary mounted semiconductor device without being discriminated from each other. Primary mounted semiconductor devices also include a multi-chip module (MCM), a chip-size package (CSP), a ball grid array (BGA) and so on.

Specifically, the primary mounted semiconductor device 10 of this embodiment is formed principally of the interposer 3 that can be cut out; a semiconductor chip 5 arranged in the form of an X-Y plane on the interposer 3 and sealed with the sealing resin 6; and the solder bump 4 electrically connected to an electrode (not illustrated) formed on the semiconductor chip 5 with the interposer 3 held therebetween. Preferably, electrode junction is established between the semiconductor chip 5 and the interposer 3, and a plurality of semiconductor chips 5 are collectively sealed with the sealing resin 6.

The interposer 3 is not particularly limited, and examples thereof include ceramic substrates, plastic (epoxy, bismaleimide triazine, polyimide etc.) substrates and silicon substrates.

The form of electrode junction between the semiconductor chip 5 and the interposer 3 is not particularly limited, and examples thereof include wire bonding through a gold wire or a copper wire, and bump junction. Examples of the material of the solder bump include gold, copper, nickel, aluminum, solder and combinations thereof. The size of the solder bump is not particularly limited, and is, for example, about 100 to 300 μm in terms of the diameter.

In the reinforcement sheet 8, the thickness of the thermosetting resin sheet 2 is preferably less than the height of the solder bump 4, more preferably 60% or less, still more preferably 58% or less, and particularly preferably 55% or less of the height of the solder bump 4. Accordingly, the solder bump 4 can extend over the thermosetting resin sheet 2 to the base material sheet 1. As a result, the solder bump 4 is exposed from the thermosetting resin sheet 2 at the time of subsequently peeling off the base material sheet 1 (see FIG. 2B), and therefore good electrical connection with the wiring substrate can be achieved. At the same time, the amount of exposure of the solder bump from the thermosetting resin sheet is easily adjusted, and therefore the base portion of the solder bump can be intensively reinforced efficiently.

(Bonding)

As shown in FIG. 2A, the reinforcement sheet 8 is bonded to the first main surface 3a of the primary mounted semiconductor device 10 on which the solder bump 4 is formed. It is preferred that bonding is performed under heating and pressing conditions from the view point of versatility and productivity, and a roll compression bonding, press compression bonding method or the like is suitably used.

Preferably, the bonding temperature is not lower than the softening point of the resin that forms the thermosetting resin sheet 2 and not higher than the curing reaction initiation temperature from the viewpoint of fluidity of the thermosetting resin sheet 2. The bonding temperature is usually selected from a temperature range of about 150° C. to 200° C. Accordingly, fluidity of the resin can be secured to sufficiently fill a gap between solder bumps the thermosetting resin sheet 2, and sufficient adhesion to the first main surface 3a of the interposer 3 can be achieved. The base material sheet 1 can also be softened, so that the base material sheet 1 can follow the solder bump 4 over the thermosetting resin sheet 2. Accordingly, the crushing of the solder bump 4 can be prevented.

Pressing is performed by applying a pressure of preferably 0.5 to 5 MPa, more preferably 1 to 3 MPa to press the reinforcement sheet from the viewpoint of strength of the semiconductor device and fluidity of the thermosetting resin sheet. Compression bonding may be performed under a reduced pressure (1 to 1000 Pa) as necessary.

After the step (A), a back surface grinding step may be performed from a second main surface (i.e., back surface) 3b of the primary mounted semiconductor device 10 on a side opposite to the first main surface 3a (not illustrated). In the back surface grinding step, only the sealing resin 6 may be ground, or the back surface of the semiconductor chip 5 may be ground. When the back surface of the semiconductor chip 5 is not resin-sealed, the back surface of the semiconductor chip 5 is directly ground. The thinning processor to be used for backside grinding of the primary mounted semiconductor device 10 is not particularly limited, and for example, a grinder (back grinder), a polishing pad or the like may be used. Backside grinding may be performed by a chemical method such as etching. Backside grinding is performed until the primary mounted semiconductor device has a desired thickness (e.g. 10 to 500 μm).

[Step (B)]

After the bonding step, the primary mounted semiconductor device 10 with the thermosetting resin sheet 2 bonded thereon is peeled off from the base material sheet 1 (FIG. 2B). When the base material sheet 1 is a fluorine-based sheet, the base material sheet 1 can be smoothly peeled off because of its releasability.

[Step (C)]

In the heat treatment step, the thermosetting resin sheet 2 is subjected to a heat treatment to cure the thermosetting resin sheet 2. Regarding conditions for the heat treatment of the thermosetting resin sheet, the heating temperature is preferably 100° C. to 200° C., more preferably 110° C. to 180° C., the heating time is preferably 3 minutes to 200 minutes, more preferably 30 minutes to 120 minutes, and a pressure may be applied as necessary. When a pressure is applied, a pressure of preferably 0.1 MPa to 10 MPa, more preferably 0.5 MPa to 5 MPa can be employed. The base material sheet 1 may be peeled off after the heat treatment of the thermosetting resin sheet 2 as long as the base material sheet 1 has heat resistance and maintains releasability even after the heat treatment.

(Dicing Step)

As in the present embodiment, when a package is configured in which a plurality of primary mounted semiconductor devices are sealed with the sealing resin 6, each of the primary mounted semiconductor devices including the semiconductor element 5 connected to the solder bump 4 with the substrate 3 interposed between the semiconductor element 5 and the solder bump 4, it is possible to perform a dicing step of dividing the package into packages each including one primary mounted semiconductor device as one unit.

First, the primary mounted semiconductor device 10 with the thermosetting resin sheet 2 and a dicing tape 11 are bonded to each other (see FIG. 2C). At this time, the primary mounted semiconductor device 10 and the dicing tape 11 are bonded to each other in such a manner that the second main surface 3b side of the primary mounted semiconductor device faces the pressure-sensitive adhesive layer 11b of the dicing tape 11. Accordingly, the thermosetting resin sheet 2 bonded to the first main surface 3a of the primary mounted semiconductor device 10 is exposed (upward in FIG. 2C).

The dicing tape 11 has a structure in which the pressure-sensitive adhesive layer 11b is laminated on the base material layer 11a. A commercially available dicing tape can also be suitably used.

(Base Material Layer)

The base material layer 11a serves as a strength matrix for the dicing tape 11. Examples include polyolefins such as low-density polyethylene, linear polyethylene, medium-density polyethylene, high-density polyethylene, ultra-low-density polyethylene, random copolymerization polypropylene, block copolymerization polypropylene, homopolypropylene, polybutene and polymethylpentene, ethylene-vinyl acetate copolymers, ionomer resins, ethylene-(meth)acrylic acid copolymers, ethylene-(meth)acrylic acid ester (random and alternating) copolymers, ethylene-butene copolymers, ethylene-hexene copolymers, polyurethane, polyesters such as polyethylene terephthalate and polyethylene naphthalate, polycarbonate, polyimide, polyether ether ketone, polyimide, polyether imide, polyamide, total aromatic polyamide, polyphenyl sulfide, aramid (paper), glass, glass cloth, fluororesins, polyvinyl chloride, polyvinylidene chloride, cellulose-based resins, silicone resins, metals (foils) and paper. When the pressure-sensitive adhesive layer 11b is ultraviolet ray-curable, the base material layer 11a is preferably permeable to ultraviolet rays.

In addition, examples of the material of the base material layer 11a include polymers such as crosslinked products of the resins described above. For the plastic film described above, an unstretched film may be used, or a film subjected to uniaxial or biaxial stretching may be used as necessary.

The surface of the base material layer 11a can be subjected to a common surface treatment, for example, a chemical or physical treatment such as a chromic acid treatment, ozone exposure, flame exposure, high-voltage electrical shock exposure or an ionized radiation treatment, or a coating treatment with a primer (e.g. adhesive substance to be described) for improving adhesion with an adjacent layer, the retention property and so on.

For the base material layer 11a, the same material or different materials can be appropriately selected and used, and one obtained by blending several materials can be used as necessary. The base material layer 11a can be provided thereon with a vapor-deposited layer of an electrically conductive substance made of a metal, an alloy, an oxide thereof, or the like and having a thickness of about 30 to 500 Å for imparting an antistatic property. An antistatic agent may be added into the base material layer to impart the antistatic property. The base material layer 11a may be a single layer or a multiple layer having two or more layers.

The thickness of the base material layer 11a is not particularly limited, and can be appropriately determined, but is generally about 5 to 200 μm, and is preferably 35 to 120 μm.

The base material layer 11a may contain various kinds of additives (e.g. colorant, filler, plasticizer, antiaging agent, antioxidant, surfactant, flame retardant, etc.).

(Pressure-Sensitive Adhesive Layer)

A pressure-sensitive adhesive to be used for formation of the pressure-sensitive adhesive layer 11b is not particularly limited as long as a pressure-sensitive adhesive can firmly retain the sealed body of the primary mounted semiconductor device 10 during dicing, and can peelably control the primary mounted semiconductor device with the thermosetting resin sheet after dicing. For example, a common pressure-sensitive adhesive such as an acryl-based pressure-sensitive adhesive or a rubber-based pressure-sensitive adhesive can be used. As the pressure-sensitive adhesive, an acryl-based pressure-sensitive adhesive with an acryl-based polymer as a base polymer is preferred from the viewpoint of ease of cleaning an electronic component such as a semiconductor wafer or glass, which must be free from staining, using an organic solvent such as an ultrapure water or an alcohol.

Examples of the acryl-based polymer include those using an acrylate as a main monomer component. Examples of the acrylate include one or more of (meth)acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester and eicosyl ester) and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth)acrylic acid alkyl ester or cycloalkyl ester as necessary for the purpose of modifying cohesive strength, heat resistance and so on. Examples of the monomer component include carboxyl group-containing monomers such as acrylic acid, methacrylic acid, carboxyethyl (meth)acrylate, carboxypentyl (meth)acrylate, itaconic acid, maleic acid, fumaric acid and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl (meth)acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of crosslinking. Examples of the polyfunctional monomer include hexanediol di(meth)acrylate, (poly)ethylene glycol di(meth)acrylate, (poly) propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy (meth)acrylate, polyester (meth)acrylate and urethane (meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization or suspension polymerization. The content of low-molecular weight substances is preferably low from the viewpoint of prevention of contamination of a clean adherend. In this respect, the number average molecular weight of the acryl-based polymer is preferably 300000 or more, further preferably about 400000 to 3000000.

For the pressure-sensitive adhesive, an external crosslinker can also be appropriately employed for increasing the number average molecular weight of an acryl-based polymer or the like as a base polymer. Specific examples of the external crosslinking methods include a method in which so called a crosslinker such as a polyisocyanate compound, an epoxy compound, an aziridine compound or a melamine-based crosslinker is added and reacted. When an external crosslinker is used, the used amount thereof is appropriately determined according to a balance with a base polymer to be crosslinked, and further a use application as a pressure-sensitive adhesive. Generally, the external crosslinker is blended in an amount of preferably about 5 parts by weight or less, further preferably 0.1 to 5 parts by weight, based on 100 parts by weight of the base polymer. Further, for the pressure-sensitive adhesive, previously known various kinds of additives, such as a tackifier and an anti-aging agent, may be used as necessary in addition to the aforementioned components.

The pressure-sensitive adhesive layer 11b can be formed by radiation curing-type pressure-sensitive adhesive. By irradiating the radiation curing-type pressure-sensitive adhesive with radiations such as ultraviolet rays, the degree of crosslinking thereof can be increased to easily reduce its adhesive power, so that peeling of the primary mounted semiconductor device with the thermosetting resin sheet can be easily performed. Examples of radiations include X-rays, ultraviolet rays, electron rays, α rays, β rays and neutron rays.

For the radiation curing-type pressure-sensitive adhesive, one having a radiation-curable functional group such as a carbon-carbon double bond and showing adherability can be used without particular limitation. Examples of the radiation curing-type pressure-sensitive adhesive may include, for example an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane (meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta (meth)acrylate, dipentaerythrithol hexa(meth)acrylate and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curing-type pressure-sensitive adhesive include, besides the addition-type radiation curing-type pressure-sensitive adhesive described previously, an intrinsic radiation curing-type pressure-sensitive adhesive using, as a base polymer, a polymer having a carbon-carbon double bond in the polymer side chain or main chain or at the end of the main chain. The intrinsic radiation curing-type pressure-sensitive adhesive is preferable because it is not required to contain, or mostly does not contain an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used without no particular limitation. Such a base polymer is preferably one having an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethylvinyl ether, 4-hydroxybutyl vinyl ether and diethylene glycol monovinyl ether, and so on is used.

For the intrinsic radiation curing-type pressure-sensitive adhesive, the base polymer (particularly acryl-based polymer) having a carbon-carbon double bond can be used alone, but the radiation curable monomer component or oligomer component within the bounds of not deteriorating properties can also be blended. The amount of the radiation curable oligomer component or the like is normally within a range of 30 parts by weight or less, preferably in a range of 0 to 10 parts by weight, based on 100 parts by weight of the base polymer.

A photopolymerization initiator is preferably included in the radiation curing-type pressure-sensitive adhesive when it is cured by ultraviolet rays or the like. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether and anisoin methyl ether; ketal-based compounds such as benzyldimethylketal; aromatic sulfonyl chloride-based compounds such as 2-naphthalenesulfonyl chloride; photoactive oxime-based compounds such as 1-phenyl-1,2-propanedione-2-(O-ethoxycarbonyl)oxime; benzophenone-based compounds such as benzophenone, benzoyl benzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

When curing hindrance by oxygen occurs at the time of the irradiation of radiations, it is desirable to block oxygen (air) from the surface of the radiation curing-type pressure-sensitive adhesive layer 11b by some method. Examples include a method in which the surface of the pressure-sensitive adhesive layer 11b is covered with a separator, and a method in which irradiation of radiations such as ultraviolet rays or the like is carried out in a nitrogen gas atmosphere.

The pressure-sensitive adhesive layer 11b may contain various kinds of additives (e.g. colorant, thickener, bulking agent, filler, tackifier, plasticizer, antiaging agent, antioxidant, surfactant, crosslinker, etc.).

The thickness of the pressure-sensitive adhesive layer 11b is not particularly limited, but is preferably about 1 to 100 μm from the viewpoint of adjustment of the breaking strength, compatibility of fixation and retention of the thermosetting resin sheet 2, and so on. The thickness of the pressure-sensitive adhesive layer 11b is preferably 2 to 80 μm, further preferably 5 to 60 μm.

In the dicing step, the primary mounted semiconductor device 10 and the thermosetting resin sheet 2 are diced to form individual pieces of primary mounted semiconductor device 10 with the thermosetting resin sheet 2 as shown in FIG. 2D. The primary mounted semiconductor device 10 obtained here is integrated with the thermosetting resin sheet 2 cut in the same shape. Dicing is performed in accordance with a usual method from the first main surface 3a side of the primary mounted semiconductor device 10 on which the thermosetting resin sheet 2 is bonded.

In this step, for example, a cutting method called full cutting in which a cut is made to the dicing tape 11 can be employed. The dicing device to be used in this step is not particularly limited, and previously known one can be used.

When expansion of the dicing tape is performed subsequently to the dicing tape, the expansion can be performed using a previously known expanding device. The expanding device includes a doughnut-shaped outer ring capable of pressing the dicing tape downward through a dicing ring, and an inner ring having a diameter smaller than that of the outer ring and supporting the dicing tape. Owing to the expanding step, neighboring components can be prevented from coming into contact with each other to cause damage at the time of picking up the primary mounted semiconductor device 10 with the thermosetting resin sheet 2.

Next, pickup is performed for collecting the fragmented primary mounted semiconductor device 10 prior to the step (D) that is a secondary mounting process. The pickup method is not particularly limited, and previously known various methods can be employed. Examples include a method in which individual pieces of the primary mounted semiconductor devices 10 are pushed up by a needle from the base material layer side of the dicing tape, and the pushed-up primary mounted semiconductor device 10 is picked up by a pickup device. The picked-up primary mounted semiconductor device 10 is integrated with the thermosetting resin sheet 2 bonded to the first main surface 3a, so that a laminate is formed.

Here, pickup is performed after irradiating the pressure-sensitive adhesive layer 11b with ultraviolet rays when the pressure-sensitive adhesive layer 11b is of an ultraviolet-ray curing-type. Consequently, adhesive power of the pressure-sensitive adhesive layer 11b to the primary mounted semiconductor device 10 decreases, so that it becomes easy to peel off the primary mounted semiconductor device 10. As a result, pickup can be performed without damaging the primary mounted semiconductor device 10. Conditions such as an irradiation intensity and an irradiation time for irradiation of ultraviolet rays are not particularly limited, and may be appropriately set as necessary. As a light source used for irradiation of ultraviolet rays, for example, a low-pressure mercury lamp, a low-pressure high-power lamp, a medium-pressure mercury lamp, an electrodeless mercury lamp, a xenon flash lamp, an excimer lamp, an ultraviolet LED or the like can be used.

[Step (D)]

In the step (D), the primary mounted semiconductor device 10 with the thermosetting resin sheet 2 is electrically connected to the wiring substrate 23 through the solder bump 4 (see FIG. 2E). Specifically, the primary mounted semiconductor device 10 is fixed to the wiring substrate 23 by a usual method such that the first main surface 3a of the primary mounted semiconductor device 10 faces the wiring substrate 23. For example, by melting a joining conductive material (not illustrated) attached on a connection pad of the wiring substrate 23 while pressing the solder bump 4 formed on the primary mounted semiconductor device 10 with the solder bump 4 being in contact with the conductive material, electrical connection between the primary mounted semiconductor device 10 and the wiring substrate 23 can be secured. Since the thermosetting resin sheet 2 is bonded on the first main surface 3a side of the primary mounted semiconductor device 10, electrical connection between the solder bump 4 and the wiring substrate 23 can be achieved while the base part of the solder bump 4 is reinforced.

In the secondary mounting process, the temperature is 200 to 300° C. as a general heating condition, and the pressure is 0 to 1000 N as a pressing condition. The thermocompression bonding treatment in the secondary mounting process may be performed in multiple stages. For example, a procedure can be employed in which the treatment is performed at 150° C. and 50 N for 10 seconds, followed by performing the treatment at 280° C. and 10 to 100 N for 10 seconds. When the thermocompression bonding treatment in multiple stages, the resin between the solder bump 4 and the pad can be efficiently removed to achieve more satisfactory junction between metals.

Examples of the wiring substrate 23 include known wiring substrates such as rigid wiring substrates, flexible wiring substrates, ceramic wiring substrates, metal core wiring substrates and organic substrates.

In the secondary mounting process, one or both of the solder bump 4 and the conductive material is melted to be connected to each other, and the temperature at the time of melting the solder bump 4 and the conductive material is normally about 260° C. (e.g. 250° C. to 300° C.). The reinforcement sheet according to this embodiment can possess such heat resistance that endures a high temperature in the secondary mounting process by forming the thermosetting resin sheet 2 with an epoxy resin or the like.

The thermosetting resin sheet 2 may be cured by applying heat in secondary mounting instead of being cured after the base material sheet 1 is peeled off, or may be cured by providing a curing step after the secondary mounting step.

[Secondary Mounted Semiconductor Device]

A secondary mounted semiconductor device obtained using the reinforcement sheet will now be described with reference to the drawings (see FIG. 2F). In a semiconductor device 20 according to this embodiment, the primary mounted semiconductor device 10 and the wiring substrate 23 are electrically connected to each other through the solder bump 4 formed on the primary mounted semiconductor device 10 and a conductive material (not illustrated) provided on the wiring substrate 23. The thermosetting resin sheet 2 is disposed at the base part of the solder bump 4 so as to reinforce the base part, and thus excellent impact resistance can be exhibited.

### Second Embodiment

In the first embodiment, a package with a semiconductor chip flip-chip-mounted on an interposer is used as a primary mounted semiconductor device, but in the second embodiment, a wafer level chip size package (WS-CSP) (hereinafter, also referred to as a “CPS”) is used.

FIG. 3 shows a secondary mounted semiconductor device 40 with a CSP secondarily mounted on a wiring substrate 43. The CSP includes a chip 45, a conductive pillar 49 and a rewiring layer 46 each formed on one surface of the chip 45, a sealing resin layer 47 laminated on the rewiring layer 46, and a solder bump 44 provided at the tip of the conductive pillar 49, and a thermosetting resin sheet 42 for reinforcing the base part of the solder bump is further laminated on the sealing resin layer 47 of the CSP. The secondary mounted semiconductor device 40 can be suitably produced by passing through steps as described in the first embodiment except that the CSP is used as a primary mounted semiconductor device.

### EXAMPLES

Hereinafter, preferred examples of the present invention will be described in detail in an illustrative manner. It is to be noted that the materials, blending amounts and so on described in examples are not intended to limit the scope of the present invention unless they are particularly specified. The term “part(s)” means part(s) by weight.

Components used in Examples will be described.

Epoxy resin 1: YSLV-80XY (bisphenol F type epoxy resin, epoxy equivalent 200 g/eq., softening point 80° C.) manufactured by Nippon Steel Chemical Co., Ltd.

Epoxy resin 2: JER828 (epoxy equivalent 185 g/eq., liquid at room temperature) manufactured by Mitsubishi Chemical Corporation

Epoxy resin 3: EPPN-501HY (epoxy equivalent 169 g/eq., softening point 60° C.) manufactured by Nippon Kayaku Co., Ltd.

Epoxy resin 4: HP7200 (epoxy equivalent 259 g/eq., softening point 61° C.) manufactured by DIC Corporation

Epoxy resin 5: YX4000H (epoxy equivalent 193 g/eq., softening point 105° C.) manufactured by Mitsubishi Chemical Corporation

Phenol resin 1: MEH 7500-3S (hydroxyl group equivalent 103 g/eq., softening point 83° C.) manufactured by Meiwa Plastic Industries, Ltd.

Phenol resin 2: LVR8210DL (hydroxyl group equivalent 104 g/eq., softening point 69° C.) manufactured by Gunei Chemical Industry Co., Ltd.

Inorganic filler 1: FB-5SDC (molten spherical silica, average particle diameter 5 μm) manufactured by Denka Company Limited

Inorganic filler 2: SO-25R (molten spherical silica, average particle diameter 0.5 μm) manufactured by Admatechs

Inorganic filler 3: FB-9454FC (molten spherical silica, average particle diameter 20 μm) manufactured by Denka Company Limited

Elastomer 1: EP-2601 (silicone-based particles) manufactured by Toray Dow Corning Co., Ltd.

Elastomer 2: SIBSTER 072T (styrene-isobutylene-styrene block copolymer) manufactured by Kaneka Corporation

Curing accelerator: 2PHZ-PW (2-phenyl-4,5-dihydroxymethylimidazole) manufactured by Shikoku Chemicals Corporation

Silane coupling agent: KBM-403 (3-glycidoxypropyltrimethoxysilane) manufactured by Shin-Etsu Chemical Co., Ltd.

Carbon black: #20 manufactured by Mitsubishi Chemical Corporation

### Examples 1 to 9 and Comparative Examples 1 to 4

As base material sheets, fluorine-based sheets (containing ethylene-tetrafluoroethylene copolymer (ETFE)) having thicknesses shown in Table 1 were prepared. The fluorine-based sheets were subjected to a plasma treatment.

In accordance with blending ratios described in Table 1, respective components were blended to obtain a blended product, and the blended product was melted and kneaded through a roll kneader at 60 to 120° C. under a reduced pressure (0.01 kg/cm²) for 10 minutes to prepare a kneaded product. Next, the obtained kneaded product was placed on a release liner and formed into a sheet shape (50 mm×50 mm) by a flat plate press method to produce a thermosetting resin sheet having a thickness of 50 μm.

The plasma-treated surface of the base material sheet and the thermosetting resin sheet were bonded by a hand roller (bonding temperature 70° C.) to produce a bump base reinforcement sheet.

<Evaluation>

The following evaluations were made on each of the prepared bump base reinforcement sheets. The results are shown in Table 1.

(Minimum Melt Viscosity)

The minimum melt viscosity of each thermosetting resin sheet at 50 to 180° C. was measured by the following procedure. A plurality of small circular pieces each having a diameter of 25 mm were cutout from the bump base reinforcement sheet. While the base material sheet and the release liner were peeled from the small piece, a thermosetting resin sheet was laminated until the thickness was about 1 mm, to prepare a measurement sample. Regarding the measurement sample, when a viscosity change was pursued with a viscoelasticity measuring apparatus “ARES” manufactured by Rheometric Scientific (measurement conditions: measuring temperature range of 50 to 180° C., temperature increase rate of 10° C./minute, frequency of 1 Hz, strain amount of 10%), the minimum value of the viscosity was read to obtain the minimum melt viscosity of the measurement sample.

(Resin Filling Property with Respect to Base Portion of Solder Bump)

The release liner on the thermosetting resin sheet having approximately the same size as that of the evaluation chip was peeled off, and the thermosetting resin sheet of the reinforcement sheet was then subjected to a flat plate vacuum press (subjected to a negative pressure for 10 seconds, and then pressed for 60 seconds) using a bonding device (VS008-1515 manufactured by Mikados Technos Co., Ltd.), to bond the thermosetting resin sheet to the solder bump forming surface of a chip, thereby producing a chip with reinforcement sheet.

<Evaluation Chip>

Size in plan view: 4.3 mm×4 mm

Chip thickness: 700 μm

Height of solder bump: 200 μm

<Bonding Conditions>

Temperature: 175° C.

Pressure: 2 MPa

Reduced-pressure atmosphere: −100 kPa (gauge pressure)

Next, the base material sheet was peeled off, and the thermosetting resin sheet was heated in an oven at 150° C. for 60 minutes to be cured. The entire chip was embedded with an embedding resin for microscopic observation to obtain an embedded article, and the embedded article was ground until a joint portion with the chip of the solder bump appeared. The cross section was observed with a scanning electron microscope (SEM; 700 times). A case where the top portion of the solder bump was not crushed and the thermosetting resin sheet did not cover the top portion of the solder bump (the solder bump was exposed from the thermosetting resin sheet) was evaluated as “◯”, and a case where the top portion of the solder bump was crushed or the thermosetting resin sheet covered the top portion of the solder bump (the solder bump was not exposed from the thermosetting resin sheet) was evaluated as “x”.

TABLE 1

| | | Example | Example | Example | Example | Example | Example | Example | Example | Example | Comparative | Comparative |
|---|---|---|---|---|---|---|---|---|---|---|---|---|
| | | 1 | 2 | 3 | 4 | 5 | 6 | 7 | 8 | 9 | Example 1 | Example 2 |
| Blending | Epoxy resin 1 | 100 | 100 | — | 100 | 100 | — | 100 | 100 | — | 100 | 100 |
| amount | Epoxy resin 2 | 96.9 | 96.9 | 29 | 96.9 | 96.9 | 29 | 96.9 | 96.9 | 29 | — | — |
| (parts by | Epoxy resin 3 | — | — | 100 | — | — | 100 | — | — | 100 | — | — |
| weight) | Epoxy resin 4 | — | — | 34 | — | — | 34 | — | — | 34 | — | — |
| | Epoxy resin 5 | — | — | — | — | — | — | — | — | — | 101 | 96.9 |
| | Phenol resin 1 | 89.6 | 89.6 | — | 89.6 | 89.6 | — | 89.6 | 89.6 | — | 89.6 | 86.3 |
| | Phenol resin 2 | — | — | 80 | — | — | 80 | — | — | 80 | — | — |
| | Inorganic filler 1 | 923.6 | 1553.7 | — | 923.6 | 1553.7 | — | 923.6 | 1553.7 | — | — | 112 |
| | Inorganic filler 2 | 245.5 | 413 | — | 245.5 | 413 | — | 245.5 | 413 | — | 759 | — |
| | Inorganic filler 3 | — | — | 3901 | — | — | 3901 | — | — | 3901 | — | 3624 |
| | Elastomer 1 | — | — | 254 | — | — | 254 | — | — | 254 | — | — |
| | Elastomer 2 | — | — | — | — | — | — | — | — | — | — | 73.9 |
| | Curing accelerator | 2.9 | 2.9 | 1.7 | 2.9 | 2.9 | 1.7 | 2.9 | 2.9 | 1.7 | 2.9 | 4.2 |
| | Silane coupling agent | 1.55 | 1.55 | 16 | 1.55 | 1.55 | 16 | 1.55 | 1.55 | 16 | 2.3 | 3.6 |
| | Carbon black | 2.9 | 4.5 | 8.8 | 2.9 | 4.5 | 8.8 | 2.9 | 4.5 | 8.8 | 2.1 | 8.2 |
| Thickness t of | | 50 | 50 | 50 | 75 | 75 | 75 | 100 | 100 | 100 | 35 | 150 |
| base material sheet t [μm] | | | | | | | | | | | | |
| Evaluation | Minimum melt | 3 | 20 | 800 | 3 | 20 | 800 | 3 | 20 | 800 | 1 | 1200 |
| | viscosity η of | | | | | | | | | | | |
| | thermosetting resin | | | | | | | | | | | |
| | sheet [Pa · s] | | | | | | | | | | | |
| | t · η | 150 | 1000 | 40000 | 225 | 1500 | 60000 | 300 | 2000 | 80000 | 35 | 180000 |
| | Exposure of | ○ | ○ | ○ | ○ | ○ | ○ | ○ | ○ | ○ | x | x |
| | solder ball | | | | | | | | | | | |

From Table 1, in Examples, the solder bump was not crushed; the solder bump was exposed from the thermosetting resin sheet; and the base portion of the solder bump was filled with the thermosetting resin sheet. On the other hand, in Comparative Example 1, the solder bump was not crushed, but the thermosetting resin sheet covered the top portion of the solder bump, and the top portion of the solder bump was not exposed. This is considered due to the fact that the value in Comparative Example 1 was lower than the lower limit value of the t·η relational expression, the rigidity of the bump base reinforcement sheet was insufficient and resin present on the solder bump could not be swept away. In Comparative Example 2, the top portion of the solder bump was confirmed to be crushed. This is considered due to the fact that the value in Comparative Example 2 was more than the upper limit of the t·η relational expression, the flexibility of the bump base reinforcement sheet deteriorated and the rigidity was too high.

### DESCRIPTION OF REFERENCE SIGNS

1 Base material sheet
2 Thermosetting resin sheet
3, 43 Interposer
3a First main surface of interposer
3b Second main surface of interposer on a side opposite to first main surface
4, 44 Solder bump
5, 45 Semiconductor chip (semiconductor element)
6 Sealing resin
8 Bump base reinforcement sheet
11 Dicing tape
10 Primary mounted semiconductor device
20, 40 Secondary mounted semiconductor device

1. A bump base reinforcement sheet comprising:
a base material sheet; and
a thermosetting resin sheet laminated on the base material sheet,
wherein
a thickness t [μm] of the base material sheet and a minimum melt viscosity η [Pa·s] of the thermosetting resin sheet at 50 to 180° C. satisfy a relational expression below:
150≤t·η≤100000.

2. The bump base reinforcement sheet according to claim 1, wherein the base material sheet has a thickness of 50 to 100 μm.

3. The bump base reinforcement sheet according to claim 1, wherein the base material sheet has a storage modulus E at 175° C. of 5×10⁶ Pa or more and 5×10⁷ Pa or less.

4. The bump base reinforcement sheet according to claim 1, wherein the base material sheet is a fluorine-based sheet.

5. The bump base reinforcement sheet according to claim 4, wherein the fluorine-based sheet comprises a copolymer of a fluorine-containing monomer and an ethylene monomer.

6. The bump base reinforcement sheet according to claim 2, wherein the base material sheet has a storage modulus E at 175° C. of 5×10⁶ Pa or more and 5×10⁷ Pa or less.

7. The bump base reinforcement sheet according to claim 2, wherein the base material sheet is a fluorine-based sheet.

8. The bump base reinforcement sheet according to claim 3, wherein the base material sheet is a fluorine-based sheet.

9. The bump base reinforcement sheet according to claim 6, wherein the base material sheet is a fluorine-based sheet.

10. The bump base reinforcement sheet according to claim 7, wherein the fluorine-based sheet comprises a copolymer of a fluorine-containing monomer and an ethylene monomer.

11. The bump base reinforcement sheet according to claim 8, wherein the fluorine-based sheet comprises a copolymer of a fluorine-containing monomer and an ethylene monomer.

12. The bump base reinforcement sheet according to claim 9, wherein the fluorine-based sheet comprises a copolymer of a fluorine-containing monomer and an ethylene monomer.
